(19) United States
(12) Patent Application Publication
(10) Pub. No.: US 2026/0343749 A1
(43) Pub. Date: Oct. 29, 2026

(54) SWITCHING ELEMENT AND ELECTRONIC DEVICE COMPRISING SAME

(71) Applicant: Samsung Electronics Co., Ltd., Suwon-si (KR)

(72) Inventors: Mincheol KIM, Suwon-si (KR); Kihyug SEONG, Suwon-si (KR); Hyoseok NA, Suwon-si (KR); John MOON, Suwon-si (KR); Dongil YANG, Suwon-si (KR)

(21) Appl. No.: 19/701,152

(22) Filed: Jun. 8, 2026

Related U.S. Application Data
(63) Continuation of application No. PCT/KR2024/013391, filed on Sep. 5, 2024.

(30) Foreign Application Priority Data
Dec. 12, 2023 (KR) 10-2023-0179674
Feb. 8, 2024 (KR) 10-2024-0019734

(51) Int. Cl. H05K 1/181; H03K 17/00; H04B 1/44; H05K 1/02; H05K 1/14

(52) U.S. Cl. CPC H05K 1/181; H03K 17/002; H04B 1/44; H05K 1/0215; H05K 1/0243; H05K 1/141; H05K 2201/1003; H05K 2201/10053; H05K 2201/10098

(57) ABSTRACT

A switching element and an electronic device including the same are provided. The switching element includes a substrate, a first conductive pad disposed in a first region of the substrate and configured to be electrically connected to a first signal line outside the switching element, a second conductive pad disposed in a second region of the substrate, the second conductive pad being configured to be electrically connected to a second signal line disposed outside and electrically connected to an external ground, and a third conductive pad disposed in a third region of the substrate, the third conductive pad being configured to be electrically connected to a third signal line disposed outside and electrically connected to the external ground, wherein the first conductive pad is configured to be electrically connected to one of the second conductive pad or the third conductive pad selectively and unconnected to the other pad so as to form a radio frequency (RF) path between the first conductive pad and the one pad electrically connected thereto, and wherein the substrate has no ground pad electrically connected to the external ground, except for the first conductive pad, the second conductive pad, and the third conductive pad.

### CROSS-REFERENCE TO RELATED APPLICATION(S)

This application is a continuation application, claiming priority under 35 U.S.C. § 365(c), of an International application No. PCT/KR2024/013391, filed on Sep. 5, 2024, which is based on and claims the benefit of a Korean patent application number 10-2023-0179674, filed on Dec. 12, 2023, in the Ministry of Intellectual Property (MOIP), and of a Korean patent application number 10-2024-0019734, filed on Feb. 8, 2024, in the Ministry of Intellectual Property (MOIP), the disclosure of each of which is incorporated by reference herein in its entirety.

### BACKGROUND

### 1. Field

The disclosure relates to a switching element and an electronic device including same.

### 2. Description of Related Art

An electronic device including a communication module may transmit radio frequency (RF) signals to an external device and receive RF signals from an external device. The electronic device may transmit and receive RF signals using an RF front end (RFFE). The RFFE may be a component that transmits and receives RF signals. For example, the RFFE may include a power amplifier, a filter, or a switching element. The electronic device may connect or disconnect an RF signal path by using a switching element of the RFFE. For example, the switching element may have a structure in which a series transistor is connected to a middle position of a transmission line configuring an RF signal path and a transistor is connected in parallel to the series transistor and the ground. The switching element may discharge a direct current (DC) to the external ground through selective switching and transmit an RF signal input through the connected RF signal path.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a switching element and an electronic device including same to improve a switching element.

Additional aspects will be set forth in part in the description which follows and, in part, will be apparent from the description, or may be learned by practice of the presented embodiments.

In accordance with an aspect of the disclosure, a switching element is provided. The switching element includes a substrate, a first conductive pad disposed in a first region of the substrate and configured to be electrically connected to a first signal line outside the switching element, a second conductive pad disposed in a second region of the substrate, the second conductive pad being configured to be electrically connected to a second signal line disposed outside and electrically connected to an external ground, and a third conductive pad disposed in a third region of the substrate, the third conductive pad being configured to be electrically connected to a third signal line disposed outside and electrically connected to the external ground, wherein the first conductive pad is configured to be electrically connected to one of the second conductive pad or the third conductive pad selectively and unconnected to the other pad so as to form an RF path between the first conductive pad and the one pad electrically connected thereto, and wherein the substrate has no ground pad electrically connected to the external ground, except for the first conductive pad, the second conductive pad, and the third conductive pad.

In accordance with another aspect of the disclosure, an electronic device is provided. The electronic device includes a first element, a second element, a first inductor, a second inductor, a switching element, and a printed circuit board (PCB) on which the first element, the second element, the first inductor, the second inductor, and the switching element are disposed, wherein the PCB includes a ground, a first signal line electrically connected to the first element, a second signal line electrically connected to a first terminal of the second element and connected to the ground through the first inductor, and a third signal line electrically connected to a second terminal of the second element and connected to the ground through the second inductor, wherein the switching element includes a substrate, a first conductive pad disposed in a first region of the substrate and electrically connected to the first signal line, a second conductive pad disposed in a second region of the substrate and connected to the second signal line, and a third conductive pad disposed in a third region of the substrate and connected to the third signal line, wherein the first conductive pad is configured to be electrically connected to one of the second conductive pad or the third conductive pad and unconnected to the other pad so as to form an RF path between the first conductive pad and the one pad electrically connected thereto, and wherein the substrate has no ground pad electrically connected to the ground, except for the first conductive pad, the second conductive pad, and the third conductive pad.

Various embodiments of the disclosure may reduce the size and cost of a switching element.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram illustrating an electronic device in a network environment according to an embodiment of the disclosure;

FIG. 2 is a diagram illustrating a configuration of a switching element according to an embodiment of the disclosure;

FIGS. 3A and 3B are diagrams illustrating a switching element that is selectively switched according to various embodiments of the disclosure;

FIG. 4 is a diagram illustrating a configuration of a switching element including more terminals according to an embodiment of the disclosure;

FIGS. 5A and 5B are diagrams comparing a switching element of the disclosure with a switching element of the related art according to various embodiments of the disclosure; and

FIGS. 6, 7, and 8 are diagrams illustrating a circuit of an electronic device including a switching element according to various embodiments of the disclosure.

The same reference numerals are used to represent the same elements throughout the drawings.

### DETAILED DESCRIPTION

The following description with reference to the drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include computer-executable instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g., a central processing unit (CPU)), a communication processor (CP, e.g., a modem), a graphical processing unit (GPU), a neural processing unit (NPU) (e.g., an artificial intelligence (AI) chip), a wireless-fidelity (Wi-Fi) chip, a Bluetooth™ chip, a global positioning system (GPS) chip, a near field communication (NFC) chip, connectivity chips, a sensor controller, a touch controller, a finger-print sensor controller, a display drive integrated circuit (IC), an audio CODEC chip, a universal serial bus (USB) controller, a camera controller, an image processing IC, a microprocessor unit (MPU), a system on chip (SoC), an IC, or the like.

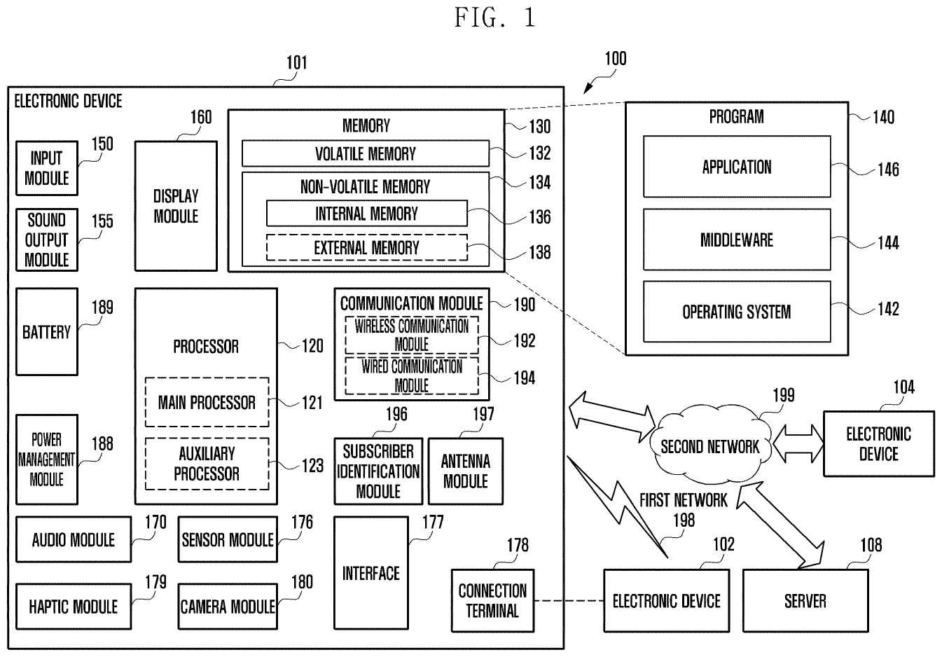

FIG. 1 is a block diagram illustrating an electronic device in a network environment according to an embodiment of the disclosure.

Referring to FIG. 1, an electronic device 101 in a network environment 100 may communicate with an external electronic device 102 via a first network 198 (e.g., a short-range wireless communication network), or at least one of an external electronic device 104 or a server 108 via a second network 199 (e.g., a long-range wireless communication network). According to an example, the electronic device 101 may communicate with the external electronic device 104 via the server 108. According to an example, the electronic device 101 may include a processor 120, memory 130, an input module 150, a sound output module 155, a display module 160, an audio module 170, a sensor module 176, an interface 177, a connection terminal 178, a haptic module 179, a camera module 180, a power management module 188, a battery 189, a communication module 190, a subscriber identification module (SIM) 196, or an antenna module 197. In some examples, at least one of the components (e.g., the connection terminal 178) may be omitted from the electronic device 101, or one or more other components may be added in the electronic device 101. In some examples, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one example, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an example, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., a sleep) state, or together with the main processor 121 while the main processor 121 is in an active state (e.g., executing an application). According to an example, the auxiliary processor 123 (e.g., an image signal processor or a communication processor) may be implemented as part of another component (e.g., the camera module 180 or the communication module 190) functionally related to the auxiliary processor 123. According to an example, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134. The non-volatile memory may include at least one of internal memory 136 and external memory 138.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an example, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an example, the display module 160 may include a touch sensor adapted to detect a touch, or a pressure sensor adapted to measure the intensity of force incurred by the touch.

The audio module 170 may convert a sound into an electrical signal and vice versa. According to an example, the audio module 170 may obtain the sound via the input module 150, or output the sound via the sound output module 155 or a headphone of an external electronic device (e.g., the external electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an example, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the external electronic device 102) directly (e.g., wiredly) or wirelessly. According to an example, the interface 177 may include, for example, a high definition multimedia interface (HDMI), a universal serial bus (USB) interface, a secure digital (SD) card interface, or an audio interface.

The connection terminal 178 may include a connector via which the electronic device 101 may be physically connected with the external electronic device (e.g., the external electronic device 102). According to an example, the connection terminal 178 may include, for example, an HDMI connector, a USB connector, an SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an example, the haptic module 179 may include, for example, a motor, a piezoelectric element, or an electric stimulator.

The camera module 180 may capture a still image or moving images. According to an example, the camera module 180 may include one or more lenses, image sensors, image signal processors, or flashes.

The power management module 188 may manage power supplied to the electronic device 101. According to one example, the power management module 188 may be implemented as at least part of, for example, a power management integrated circuit (PMIC).

The battery 189 may supply power to at least one component of the electronic device 101. According to an example, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the external electronic device 102, the external electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an example, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a fifth generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the external electronic device 104), or a network system (e.g., the second network 199). According to an example, the wireless communication module 192 may support a peak data rate (e.g., 20 gigabits per second (Gbps) or more) for implementing eMBB, loss coverage (e.g., 164 decibels (dB) or less) for implementing mMTC, or user plane (U-plane) latency (e.g., 0.5 milliseconds (ms) or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an example, the antenna module 197 may include an antenna including a radiating element including a conductive material or a conductive pattern formed in or on a substrate (e.g., a printed circuit board (PCB)). According to an example, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an example, another component (e.g., a radio frequency integrated circuit (RFIC)) other than the radiating element may be additionally formed as part of the antenna module 197.

According to various examples, the antenna module 197 may form an mmWave antenna module. According to an example, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an example, commands or data may be transmitted or received between the electronic device 101 and the external electronic device 104 via the server 108 coupled with the second network 199. Each of the external electronic devices 102 or 104 may be a device of a same type as, or a different type, from the electronic device 101. According to an example, all or some of operations to be executed at the electronic device 101 may be executed at one or more of the external electronic devices (e.g., the external electronic devices 102 and 104 or the server 108). For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an example, the external electronic device 104 may include an Internet-of-things (IoT) device. The server 108 may be an intelligent server using machine learning and/or a neural network. According to an example, the external electronic device 104 or the server 108 may be included in the second network 199. The electronic device 101 may be applied to intelligent services (e.g., a smart home, a smart city, a smart car, or healthcare) based on 5G communication technology or IoT-related technology.

The electronic device according to various examples may be one of various types of electronic devices. The electronic devices may include, for example, a portable communication device (e.g., a smartphone), a computer device, a portable multimedia device, a portable medical device, a camera, a wearable device, or a home appliance. According to an example of the disclosure, the electronic devices are not limited to those described above.

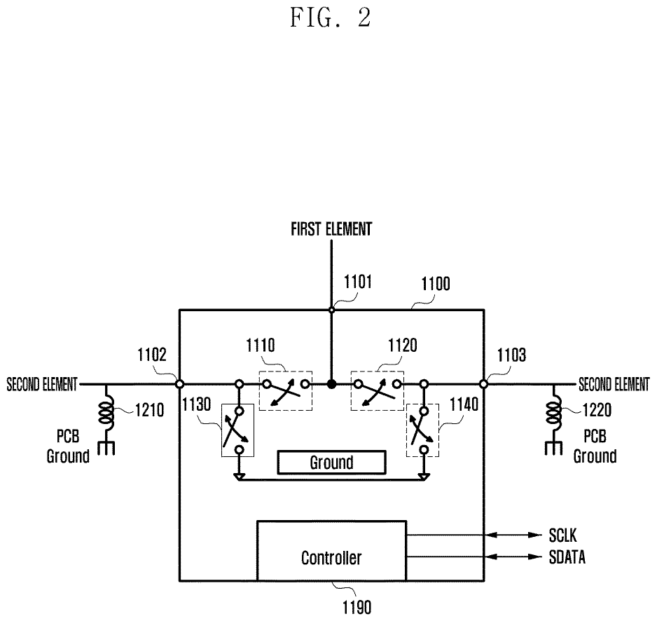

FIG. 2 is a diagram illustrating a configuration of a switching element according to an embodiment of the disclosure.

Referring to FIG. 2, a switching element 1100 according to an embodiment of the disclosure may include multiple terminals (or pins). For example, the switching element 1100 may include a first terminal 1101, a second terminal 1102, and a third terminal 1103. For example, the first terminal 1101 may be connected to a first element, and the second terminal 1102 and the third terminal 1103 may be connected to a second element. For example, the first element may be an antenna, and the second element may be a transceiver. As an example, the first element and the second element may be transceivers. The switching element 1100 may be directly connected to the first element and/or the second element and may be connected thereto via other elements (e.g., a multiplexer, an amplifier, a coupling element). The second terminal 1102 may be connected to a ground (e.g., a common ground outside the switching element 1100) through a first inductor 1210 disposed outside the switching element 1100, and the third terminal 1103 may be connected to the ground through a second inductor 1220 disposed outside the switching element 1100. As an example, the inductance of the first inductor 1210 and the second inductor 1220 may be in the range of about 22 nH to about 56 nH.

For example, the switching element 1100 may include a substrate. The switching element 1100 may include a first conductive pad disposed in the first region of the substrate and configured to be electrically connected to a first signal line outside the switching element 1100. The first conductive pad may be connected to the first terminal 1101 disposed on the substrate. As an example, the first signal line may be a signal line that electrically connects the first conductive pad (or the first terminal 1101) of the switching element 1100 to the first element. The switching element 1100 may include a second conductive pad disposed in the second region of the substrate. For example, the second conductive pad may be configured to be connected to the second terminal 1102 disposed on the substrate and connected to a second signal line that is electrically connected to an external ground. As an example, the second signal line may be a signal line that electrically connects the second conductive pad (or the second terminal 1102) of the switching element 1100 and the second element. The first inductor 1210 may be connected to the second signal line outside the switching element 1100. The second conductive pad may be configured to be electrically connected to one end of the first inductor 1210. The switching element 1100 may include a third conductive pad disposed in a third region of the substrate. For example, the third conductive pad may be configured to be connected to the third terminal 1103 disposed on the substrate and connected to a third signal line that is electrically connected to an external ground. As an example, the third signal line may be a signal line that electrically connects the third conductive pad (or the third terminal 1103) of the switching element 1100 and the second element. The second inductor 1220 may be connected to the third signal line outside the switching element 1100. The third conductive pad (or the third terminal 1103) may be configured to be electrically connected to one end of the second inductor 1220. For example, the first conductive pad (or the first terminal 1101) may be configured to be electrically connected to one of the second conductive pad (or the second terminal 1102) and the third conductive pad (or the third terminal 1103) and not to be connected to the other. The first conductive pad may define an RF path with a single electrically connected pad.

According to an embodiment of the disclosure, the switching element 1100 may include multiple switches. The multiple switches may be disposed on the substrate. A first switch 1110 may be disposed between and connected to the second terminal 1102 and the first terminal 1101 in series, and a third switch 1130 may be disposed between and connected to an internal ground of the switching element 1100 and a path between the second terminal 1102 and the first switch 1110. A second switch 1120 may be disposed between and connected to the third terminal 1103 and the first terminal 1101 in series, and a fourth switch 1140 may be disposed between and connected to the internal ground of the switching element 1100 and a path between the third terminal 1103 and the second switch 1120.

According to an embodiment of the disclosure, the switching element 1100 may include a controller 1190. For example, the controller 1190 may receive a clock signal SCLK and a data signal SDATA from a processor (e.g., the processor 120 in FIG. 1) of an electronic device 101 (e.g., the electronic device 101 in FIG. 1). The controller 1190 may control the turning on/off of the first switch 1110, the second switch 1120, the third switch 1130, and the fourth switch 1140 according to the received clock signal (SCLK) and data signal (SDATA).

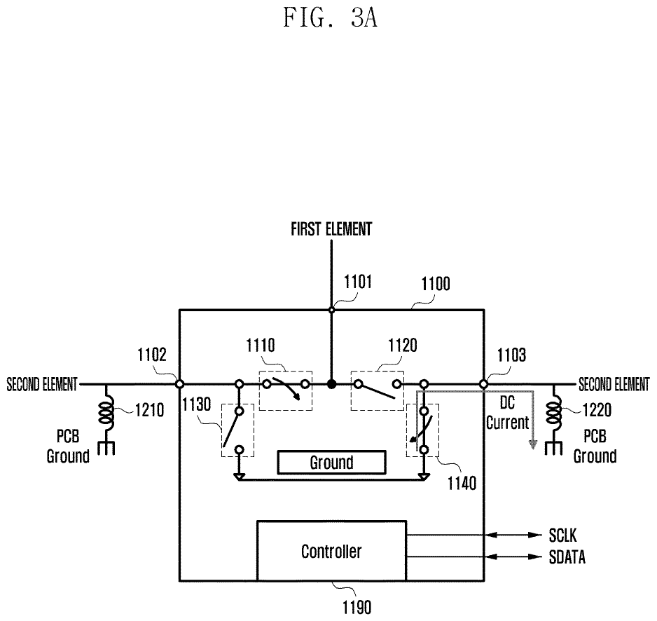

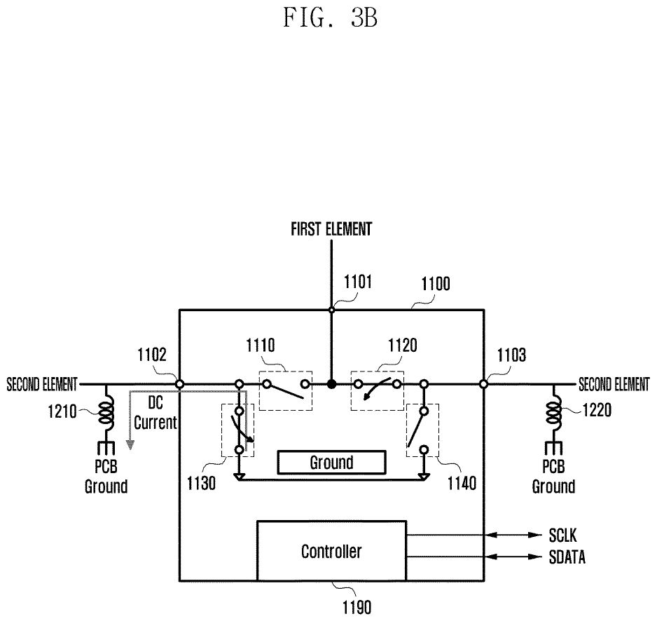

FIGS. 3A and 3B are diagrams illustrating a switching element selectively switched according to various embodiments of the disclosure.

Referring to FIG. 3A, the switching element 1100 having a first RF path formed between the first terminal 1101 and the second terminal 1102 is illustrated. For example, the switching element 1100 may turn on the first switch 1110, turn off the third switch 1130, turn off the second switch 1120, and turn on the fourth switch 1140 under the control of the controller 1190. In the switching element 1100, an electrical path may be formed between the first terminal 1101 and the second terminal 1102 by the first switch 1110 being turned-on, and an electrical path may be formed between the internal ground of the switching element 1100 and the third terminal 1103 by the fourth switch 1140 being turned-on. An RF signal may be transmitted through the electrical path formed between the first terminal 1101 and the second terminal 1102, and a DC current may be transmitted through the electrical path formed between the internal ground and the third terminal 1103.

For example, the switching element 1100 may transmit an RF signal input from the first element connected to the first terminal 1101 to the second element connected to the second terminal 1102 through a first RF path. Alternatively, the switching element 1100 may transmit an RF signal input from the second element connected to the second terminal 1102 to the first element connected to the first terminal 1101 through the first RF path. In an embodiment of the disclosure, the first inductor 1210 may be connected to a path between the second terminal 1102 and the second element. The first inductor 1210 may be disposed between and connected in parallel to the ground and the path between the second terminal 1102 and the second element. For example, the resistance of the inductor to a high-frequency signal may be close to infinity. Therefore, the RF signal output through the second terminal 1102 may be input to the second element without being affected by the first inductor 1210.

The RF signal may include a DC current, and the switching element needs to discharge the DC current to the ground. The switching element according to the comparative example may include a ground pad. One side of the ground pad may be connected to the internal ground of the switching element, and the other side may be connected to the external ground of the switching element 1100. The switching element according to the comparative example may form a discharge path for discharging a DC current from the internal ground to the external ground through the ground pad. The ground pad is formed to be of a size equal to or larger than a predetermined size. Because the switching element is very small (e.g., about 1.1 mm×about 1.1 mm), the ratio of the area occupied by the ground pad on the switching element may be very large. The switching element according to the comparative example may have limitations in reducing the size of the components due to the ground pad formed inside, and the cost may increase due to the process for forming the ground pad.

An internal ground pad may be removed from the switching element 1100 according to an embodiment of the disclosure. In addition, the switching element 1100 may configure a discharge path that discharges a DC current from the internal ground to the external ground through an inductor connected to the outside of the switching element 1100. According to an embodiment of the disclosure, the switching element 1100 includes no ground pad, thereby reducing the size of the switching element 1100, and since the process for forming a ground pad is not required, the cost may be reduced.

For example, the switching element 1100 may configure a discharge path for discharging a DC current from the internal ground to an external ground through the second inductor 1220 that is connected to the path between the third terminal 1103 and the second element. The second inductor 1220 may be disposed between and connected in parallel to the path between the third terminal 1103 and the second element and the ground. For example, the resistance of the inductor to a DC signal may be close to zero. Therefore, the DC current discharged to the outside of the switching element 1100 through the third terminal 1103 may flow to the ground.

Referring to FIG. 3B, the switching element 1100 having a second RF path formed between the first terminal 1101 and the third terminal 1103 is illustrated. For example, the switching element 1100 may turn off the first switch 1110, turn on the third switch 1130, turn on the second switch 1120, and turn off the fourth switch 1140 under the control of the controller 1190. In the switching element 1100, an electrical path may be formed between the first terminal 1101 and the third terminal 1103 by the second switch 1120 being turned on, and an electrical path may be formed between the internal ground of the switching element 1100 and the second terminal 1102 by the third switch 1130 being turned on. An RF signal may be transmitted through the electrical path formed between the first terminal 1101 and the third terminal 1103, and a DC current may be transmitted through the electrical path formed between the internal ground and the second terminal 1102.

For example, the switching element 1100 may transmit an RF signal input from the first element connected to the first terminal 1101 to the second element connected to the third terminal 1103 through a second RF path. Alternatively, the switching element 1100 may transmit an RF signal input from the second element connected to the third terminal 1103 to the first element connected to the first terminal 1101 through the second RF path. The second inductor 1220 may be connected to a path between the third terminal 1103 and the second element. The second inductor 1220 may be disposed between and connected in parallel to the path between the third terminal 1103 and the second element and the ground. Since the resistance of the inductor to high-frequency signals is close to infinite, the RF signal output through the third terminal 1103 may be input to the second element without being affected by the second inductor 1220.

For example, the switching element 1100 may configure a discharge path for discharging a DC current from the internal ground to an external ground through the first inductor 1210 that is connected to the path between the second terminal 1102 and the second element. The first inductor 1210 may be disposed between and connected in parallel to the path between the second terminal 1102 and the second element and the ground. Since the resistance of the inductor to the DC signal is close to zero, the DC current discharged to the outside of the switching element 1100 through the second terminal 1102 may flow to the ground.

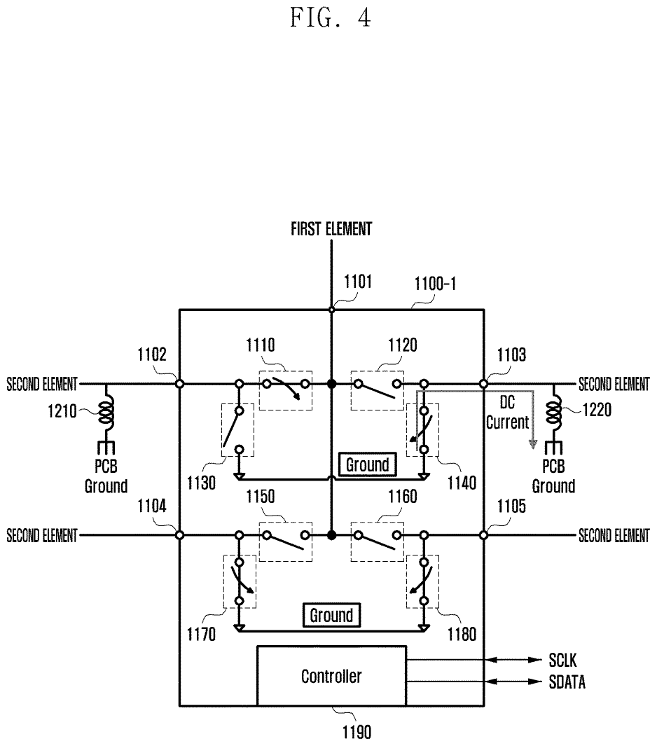

FIG. 4 is a diagram illustrating a configuration of a switching element including more terminals according to an embodiment of the disclosure.

Referring to FIG. 4, a switching element 1100-1 including a first terminal 1101, a second terminal 1102, a third terminal 1103, a fourth terminal 1104, and a fifth terminal 1105 is illustrated. Although a switching element having five terminals is illustrated in FIG. 4, the switching element may include a different number of terminals. For example, the switching element may include four, six, or seven or more terminals.

For example, the first terminal 1101 may be connected to the first element, and the second terminal 1102, the third terminal 1103, the fourth terminal 1104, and the fifth terminal 1105 may be connected to the second element. For example, the first element may be an antenna, and the second element may be a transceiver. As an example, the first element and the second element may be transceivers. The second terminal 1102 may be connected to the ground through the first inductor 1210 disposed outside the switching element 1100-1, and the third terminal 1103 may be connected to the ground through the second inductor 1220 disposed outside the switching element 1100-1.

According to an embodiment of the disclosure, the switching element 1100-1 may include multiple switches. A first switch 1110 may be disposed between and connected in series to a second terminal 1102 and a first terminal 1101, and a third switch 1130 may be disposed between and connected to an internal ground and a path between the second terminal 1102 and the first switch 1110. A second switch 1120 may be disposed between and connected in series to a third terminal 1103 and the first terminal 1101, and a fourth switch 1140 may be disposed between and connected to the internal ground and a path between the third terminal 1103 and the second switch 1120. A fifth switch 1150 may be disposed between and connected in series to a fourth terminal 1104 and the first terminal 1101, and a seventh switch 1170 may be disposed between and connected to the internal ground and a path between the fourth terminal 1104 and the fifth switch 1150. A sixth switch 1160 may be disposed between and connected in series to a fifth terminal 1105 and the first terminal 1101, and an eighth switch 1180 may be disposed between and connected to the internal ground and a path between the fifth terminal 1105 and the seventh switch 1170.

For example, the switching element 1100-1 may form a first RF path between the first terminal 1101 and the second terminal 1102. The switching element 1100-1 may turn on the first switch 1110, turn off the third switch 1130, turn off the second switch 1120, and turn on the fourth switch 1140 under the control of the controller 1190. In addition, the switching element 1100-1 may turn off the fifth switch 1150, turn on the seventh switch 1170, turn off the sixth switch 1160, and turn on the eighth switch 1180.

In the switching element 1100, an electrical path may be formed between the first terminal 1101 and the second terminal 1102 by the first switch 1110 being turned-on. The electrical path between the internal ground of the switching element 1100-1 and the third terminal 1103 may be formed by the turned-on fourth switch 1140, the electrical path between the internal ground of the switching element 1100-1 and the fourth terminal 1104 may be formed by the turned-on seventh switch 1170, and the electrical path between the internal ground of the switching element 1100-1 and the fifth terminal 1105 may be formed by the turned-on eighth switch 1180. An RF signal may be transmitted through the electrical path formed between the first terminal 1101 and the second terminal 1102. A DC current may be transmitted through the electrical path formed between the internal ground and the third terminal 1103, the electrical path formed between the internal ground and the fourth terminal 1104, and the electrical path formed between the internal ground and the fifth terminal 1105.

For example, the switching element 1100-1 may transmit an RF signal input from the first element connected to the first terminal 1101 to the second element connected to the second terminal 1102 through a first RF path. Alternatively, the switching element 1100-1 may transmit an RF signal input from the second element connected to the second terminal 1102 to the first element connected to the first terminal 1101 through the first RF path. The first inductor 1210 may be connected to the outside of the second terminal 1102. The first inductor 1210 may be disposed between and connected in parallel to the ground and the path between the second terminal 1102 and the second element. Since the resistance of the inductor to high-frequency signals is close to infinite, the RF signal output through the second terminal 1102 may be input to the second element without being affected by the first inductor 1210.

For example, the switching element 1100-1 may configure a discharge path through which a DC current is discharged from the internal ground to the ground outside the switching element 1100-1 through the second inductor 1220 connected to the outside of the third terminal 1103. The second inductor 1220 may be disposed between and connected in parallel to the ground and the path between the third terminal 1103 and the second element. As an example, since the resistance of the inductor to the DC signal is close to zero, the DC current discharged to the outside of the switching element 1100-1 through the third terminal 1103 may flow to the ground.

FIG. 4 illustrates the first inductor 1210 connected to the second terminal 1102 and the second inductor 1220 connected to the third terminal 1103, but, as an example, a third inductor connected to the outside of the fourth terminal 1104 and/or a fourth inductor connected to the outside of the fifth terminal 1105 may be included. The switching element 1100-1 may configure a discharge path for discharging a DC current from the internal ground to the external ground through the fourth terminal 1104 and the third inductor, and/or a discharge path for discharging a DC current from the internal ground to the external ground through the fifth terminal 1105 and the fourth inductor.

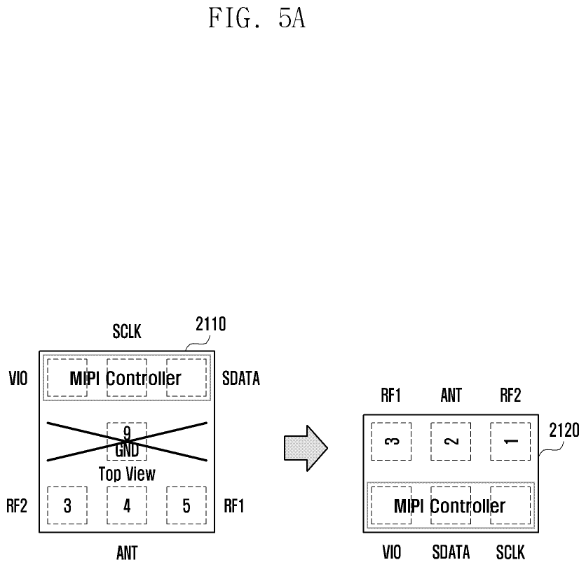

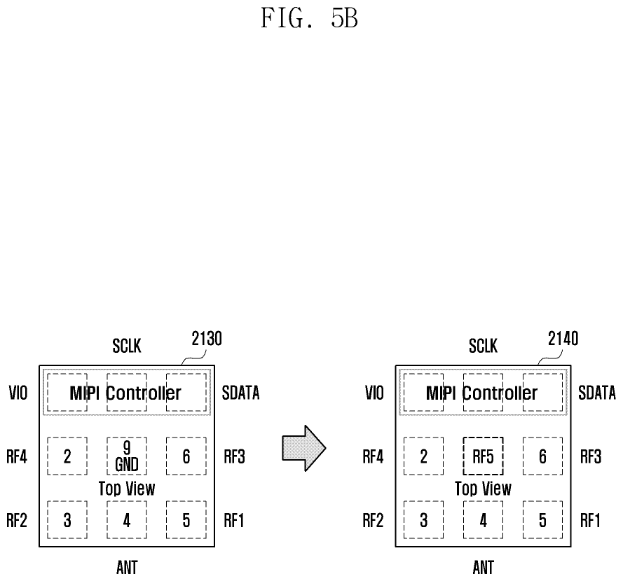

FIGS. 5A and 5B are diagrams comparing a switching element of the disclosure with a switching element of the related art according to various embodiments of the disclosure.

Referring to FIG. 5A, a switching element 2110 according to a comparative example and a switching element 2120 with a ground pad removed according to an embodiment of the disclosure are illustrated. The switching element 2110 according to the comparative example may include a ground pad in the central region. For example, the switching element 2110 according to the comparative example may have a size of about 1.1 mm×1.1 mm. The switching element 2120 according to an embodiment of the disclosure may include no ground pad. As an example, the switching element 2120 according to an embodiment of the disclosure may have a size of about 1.1 mm×0.7 mm. Therefore, the switching element 2120 according to an embodiment of the disclosure may reduce the size of components.

Referring to FIG. 5B, a switching element 2130 according to a comparative example and a switching element 2140 with a ground pad removed according to an embodiment of the disclosure are illustrated. The switching element 2130 according to the comparative example may include a ground pad in the central region. The switching element 2140 according to an embodiment of the disclosure may include no ground pad and may include an additional terminal in the ground pad region. For example, the switching element 2130 according to the comparative example and the switching element 2140 according to an embodiment of the disclosure may have a size of about 1.1 mm×1.1 mm. The switching element 2140 according to an embodiment of the disclosure may have the same size as the switching element 2130 according to the comparative example but may additionally configure a path for transmitting an RF signal.

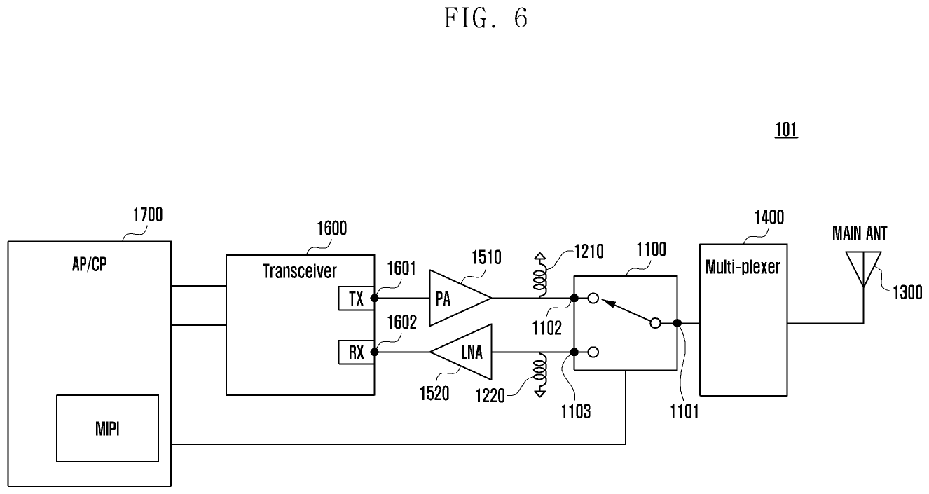

FIGS. 6, 7, and 8 are diagrams illustrating a circuit of an electronic device including a switching element according to various embodiments of the disclosure.

Referring to FIG. 6, a circuit of an electronic device 101 including a switching element 1100 that transmits an RF signal between a first element and a second element is illustrated.

According to an embodiment of the disclosure, the electronic device 101 may include an antenna 1300, a multiplexer 1400, a switching element 1100, a first inductor 1210, a second inductor 1220, a power amplifier (PA) 1510, a low-noise amplifier (LNA) 1520, a transceiver 1600, and/or a processor 1700. For example, the electronic device 101 may include a printed circuit board (PCB). For example, at least a portion of the elements of the electronic device 101 may be disposed on the printed circuit board. The antenna 1300 may receive an RF signal from the outside or transmit an RF signal of the electronic device 101 to the outside. The antenna 1300 may be connected to the multiplexer 1400. The multiplexer 1400 may connect various input lines to a single output line. The multiplexer 1400 may be connected to the switching element 1100.

The switching element 1100 may include multiple terminals. For example, the switching element 1100 may include three terminals. The first terminal 1101 may be connected to the first element, and the second terminal 1102 and the third terminal 1103 may be connected to the second element. As an example, the first element may be an antenna 1300, and the second element may be a transceiver 1600. The first terminal 1101 of the switching element 1100 illustrated in FIG. 6 may be connected to the antenna 1300. The second terminal 1102 of the switching element 1100 may be connected to an output terminal (Tx) 1601 of the transceiver 1600. The power amplifier (PA) 1510 for amplifying an output signal may be disposed between and connected to the second terminal 1102 of the switching element 1100 and the output terminal 1601 of the transceiver 1600. The third terminal 1103 of the switching element 1100 may be connected to an input terminal (Rx) 1602 of the transceiver 1600. A low noise amplifier (LNA) 1520 that amplifies the input signal while reducing noise may be disposed between and connected to the third terminal 1103 of the switching element 1100 and the input terminal 1602 of the transceiver 1600. For example, the transceiver 1600 illustrated in FIG. 6 includes the output terminal 1601 and the input terminal 1602, but the transceiver 1600 may include at least one of the output terminal or the input terminal. The first inductor 1210 may be connected to the path between the second terminal 1102 of the switching element 1100 and the power amplifier 1510, and the second inductor 1220 may be connected to the path between the third terminal 1103 and the low noise amplifier 1520. The first inductor 1210 may be disposed between and connected in parallel to the path between the second terminal 1102 of the switching element 1100 and the power amplifier 1510 and the ground of the electronic device 101, and the second inductor 1220 may be disposed between and connected in parallel to the ground of the electronic device 101 and the path between the third terminal 1103 of the switching element 1100 and the low noise amplifier 1520.

The transceiver 1600 and the switching element 1100 may be connected to the processor 1700. For example, the processor 1700 may control the transceiver 1600 and the switching element 1100 or transmit a clock signal and/or a data signal.

As an example, an RF signal received by the antenna 1300 may be transmitted to the switching element 1100 through the multiplexer 1400. The transmitted RF signal is a signal input from the outside, so the switching element 1100 may control an internal switch to form a first electrical path between the first terminal 1101 and the third terminal 1103. For example, the formed first electrical path may be a second RF path. The switching element 1100 may transmit an RF signal to the input terminal 1602 of the transceiver 1600 through the second RF path. The RF signal output from the switching element 1100 may be amplified while being reduced in noise by the LNA 1520 and then transmitted to the transceiver 1600. In addition, the switching element 1100 may form a second electrical path between the second terminal 1102 and the ground of the electronic device 101. For example, the formed second electrical path may be a DC current path. The switching element 1100 may discharge the DC current to the ground through the first inductor 1210 on the DC current path.

For example, the RF signal generated by the transceiver 1600 may be transmitted to the switching element 1100 through the output terminal 1601 of the transceiver 1600. The RF signal output from the transceiver 1600 may be amplified by the power amplifier 1510 and then transmitted to the switching element 1100. The transmitted RF signal is a signal input through the second terminal 1102 of the switching element 1100, and therefore, the switching element 1100 may form the first electrical path between the first terminal 1101 and the second terminal 1102 by controlling the internal switch. For example, the formed first electrical path may be a first RF path. The switching element 1100 may transmit an RF signal to the antenna 1300 through the first RF path. The RF signal may be transmitted to the antenna 1300 via the multiplexer 1400. In addition, the switching element 1100 may form the second electrical path between the third terminal 1103 and the ground of the electronic device 101. For example, the formed second electrical path may be a DC current path. The switching element 1100 may discharge the DC current to the ground through the second inductor 1220 on the DC current path.

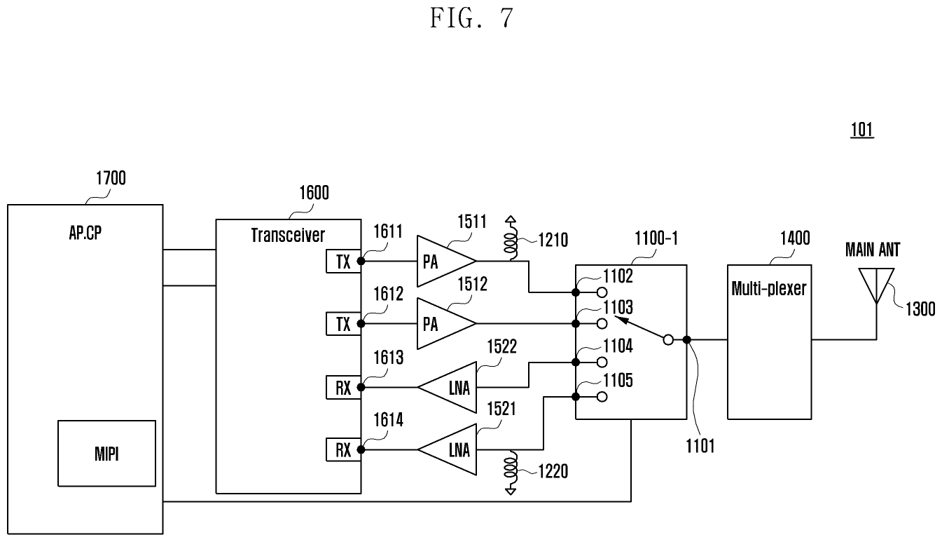

Referring to FIG. 7, a circuit of an electronic device 101 including a switching element 1100-1 including an additional terminal for transmitting an RF signal between a first element and a second element is illustrated.

According to an embodiment of the disclosure, the electronic device 101 may include an antenna 1300, a multiplexer 1400, a switching element 1100-1, a first inductor 1210, a second inductor 1220, a first power amplifier (PA) 1511, a second PA 1512, a first low-noise amplifier (LNA) 1521, a second LNA 1522, a transceiver 1600, and/or a processor 1700. The antenna 1300, the multiplexer 1400, the first inductor 1210, the second inductor 1220, the first PA 1511, the second PA 1512, the first LNA 1521, the second LNA 1522, the transceiver 1600, and the processor 1700 illustrated in FIG. 7 are similar to those described in FIG. 6, and thus the switching element 1100-1 will be described in FIG. 7.

According to an embodiment of the disclosure, the switching element 1100-1 may include multiple terminals. For example, the switching element 1100-1 may include five terminals. A first terminal 1101 may be connected to a first element, and a second terminal 1102, a third terminal 1103, a fourth terminal 1104, and a fifth terminal 1105 may be connected to a second element. As an example, the first element may be an antenna 1300, and the second element may be a transceiver 1600. The first terminal 1101 of the switching element 1100-1 illustrated in FIG. 7 may be connected to the antenna 1300. The second terminal 1102 and the third terminal 1103 of the switching element 1100-1 may be connected to output terminals (Tx) 1611 and 1612 of the transceiver 1600. The first PA 1511 and the second PA 1512 may be disposed between and connected to the second terminal 1102 and the third terminal 1103 of the switching element 1100-1 and the output terminals 1611 and 1612 of the transceiver 1600, respectively. The fourth terminal 1104 and the fifth terminal 1105 of the switching element 1100-1 may be connected to input terminals (Rx) 1613 and 1614 of the transceiver 1600. The first LNA 1521 and the second LNA 1522 may be disposed between and connected to the fourth terminal 1104 and the fifth terminal 1105 of the switching element 1100-1 and the input terminals 1613 and 1614 of the transceiver 1600. The first inductor 1210 may be connected to the path between the second terminal 1102 of the switching element 1100-1 and the first PA 1511, and the second inductor 1220 may be connected to the path between the fifth terminal 1105 and the first LNA 1521. The first inductor 1210 may be disposed between and connected in parallel to the ground of the electronic device 101 and the path between the second terminal 1102 of the switching element 1100-1 and the first PA 1511, and the second inductor 1220 may be disposed between and connected in parallel to the ground of the electronic device 101 and the path between the fifth terminal 1105 of the switching element 1100-1 and the first LNA 1521.

As an example, an RF signal received by the antenna 1300 may be transmitted to the switching element 1100-1 through the multiplexer 1400. The transmitted RF signal is a signal input from the outside, so the switching element 1100-1 may control an internal switch to form a first electrical path between the first terminal 1101 and the fourth terminal 1104. Alternatively, the switching element 1100-1 may form a first electrical path between the first terminal 1101 and the fifth terminal 1105. For example, the formed first electrical path may be a second RF path. The switching element 1100-1 may transmit an RF signal to the input terminals 1613 and 1614 of the transceiver 1600 through the second RF path. In addition, the switching element 1100-1 may form a second electrical path between the ground of the electronic device 101 and the remaining terminals (e.g., the second terminal 1102, the third terminal 1103, and the fifth terminal 1105) excluding the terminals (e.g., the first terminal 1101 and the fourth terminal 1104) with which the second RF path is formed. For example, the formed second electrical path may be a DC current path. The switching element 1100 may discharge the DC current to the ground through the first inductor 1210 on the DC current path.

As an example, the RF signal generated by the transceiver 1600 may be transmitted to the switching element 1100-1 through the output terminals 1611 and 1612 of the transceiver 1600. The transmitted RF signal is a signal input through the second terminal 1102 or the third terminal 1103 of the switching element 1100-1, and thus, the switching element 1100-1 may form the first electrical path between the first terminal 1101 and the second terminal 1102 by controlling the internal switch. Alternatively, the switching element 1100-1 may form a first electrical path between the first terminal 1101 and the third terminal 1103. For example, the formed first electrical path may be a first RF path. The switching element 1100-1 may transmit an RF signal to the antenna 1300 through the first RF path. In addition, the switching element 1100-1 may form a second electrical path between the ground of the electronic device 101 and the remaining terminals (e.g., the third terminal 1103, the fourth terminal 1104, and the fifth terminal 1105), excluding the terminals (e.g., the first terminal 1101 and the second terminal 1102) with which the first RF path is formed. For example, the formed second electrical path may be a DC current path. The switching element 1100-1 may discharge the DC current to the ground through the second inductor 1220 on the DC current path.

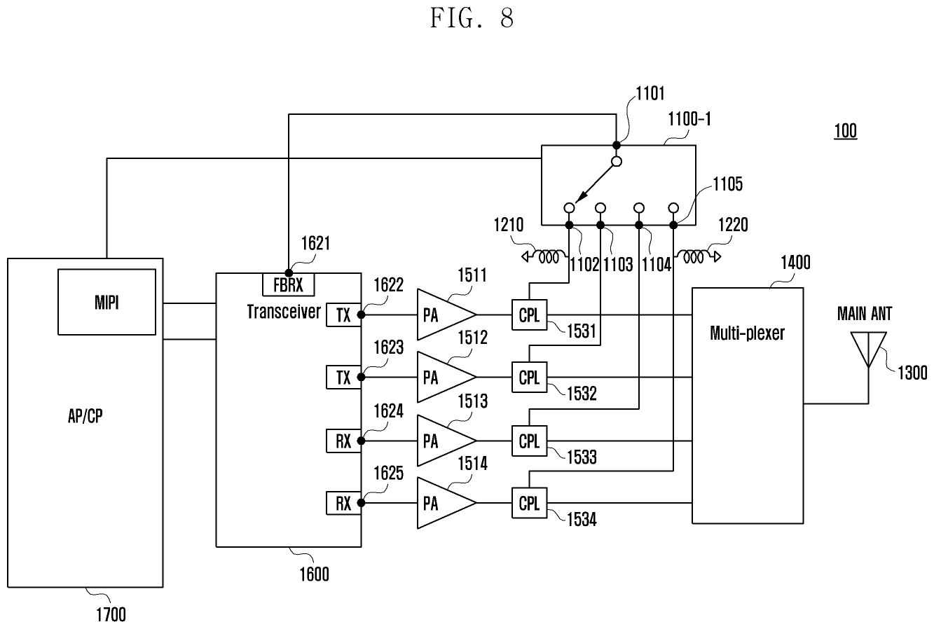

Referring to FIG. 8, a circuit of an electronic device 101 including a switching element 1100-1 disposed and connected between a first element and a second element is illustrated.

According to an embodiment of the disclosure, the electronic device 101 may include an antenna 1300, a multiplexer 1400, a switching element 1100-1, a first inductor 1210, a second inductor 1220, a first coupling circuit 1531, a second coupling circuit 1532, a third coupling circuit 1533, a fourth coupling circuit 1534, a first PA 1511, a second PA 1512, a third PA 1513, a fourth PA 1514, a transceiver 1600, and/or a processor 1700.

The antenna 1300 may receive an RF signal from the outside or transmit an RF signal of the electronic device 101 to the outside. The antenna 1300 may be connected to the multiplexer 1400. The multiplexer 1400 may connect various input lines to a single output line. For example, the multiple terminals of the multiplexer 1400 may be connected to the first coupling circuit 1531, the second coupling circuit 1532, the third coupling circuit 1533, or the fourth coupling circuit 1534, respectively. For example, the first coupling circuit 1531, the second coupling circuit 1532, the third coupling circuit 1533, or the fourth coupling circuit 1534 may be connected to at least one output terminal (Tx) 1622, 1623, 1624, or 1625 of the transceiver 1600 and at least one terminal 1102, 1103, 1104, or 1105 of the switching element 1100-1, respectively.

According to an embodiment of the disclosure, the switching element 1100-1 may include multiple terminals. For example, the switching element 1100-1 may include five terminals. A first terminal 1101 may be connected to a first element, and a second terminal 1102, a third terminal 1103, a fourth terminal 1104, and a fifth terminal 1105 may be connected to a second element. As an example, the first element and the second element may be the transceiver 1600. The first terminal 1101 of the switching element may be connected to a feedback receiver (FBRX) terminal 1621 of the transceiver 1600. The remaining terminals (e.g., the second terminal 1102, the third terminal 1103, the fourth terminal 1104, and the fifth terminal 1105) of the switching element, excluding the first terminal 1101, may be connected to the PAs (e.g., the first PA 1511, the second PA 1512, the third PA 1513, and the fourth PA 1514) and the coupling circuits (e.g., the first coupling circuit 1531, the second coupling circuit 1532, the third coupling circuit 1533, and the fourth coupling circuit 1534). The first inductor 1210 may be connected to a path between the second terminal 1102 of the switching element 1100-1 and the first coupling circuit 1531, and the second inductor 1220 may be connected to a path between the fifth terminal 1105 and the fourth coupling circuit 1534. For example, the first inductor 1210 may be disposed between and connected in parallel to the path between the second terminal 1102 of the switching element 1100-1 and the first coupling circuit 1531 and the ground of the electronic device 101, and the second inductor 1220 may be disposed between and connected in parallel to the ground of the electronic device 101 and the path between the fifth terminal 1105 of the switching element 1100-1 and the fourth coupling circuit 1534.

For example, an RF signal generated by the transceiver 1600 may be output through an output terminals 1622, 1623, 1624, or 1625 of the transceiver 1600. An RF signal output from the transceiver 1600 may be transmitted to the antenna 1300 via a power amplifier (PA), a coupling circuit, and a multiplexer. In addition, an RF signal output from the transceiver 1600 may be transmitted to the switching element 1100-1 via the PA and the coupling circuit.

As an example, an RF signal output from the first output terminal 1622 of the transceiver 1600 may be transmitted to the antenna 1300 via the first PA 1511, the first coupling circuit 1531, and the multiplexer 1400. In addition, an RF signal output from the first output terminal 1622 of the transceiver 1600 may be transmitted to the second terminal 1102 of the switching element 1100-1 via the first PA 1511 and the first coupling circuit 1531. The switching element 1100-1 may form a first electrical path between the first terminal 1101 and the second terminal 1102 by controlling an internal switch. For example, the formed first electrical path may be a first RF path. The switching element 1100-1 may transmit an RF signal through the first RF path to the FBRX terminal 1621 of the transceiver 1600. In addition, the switching element 1100-1 may form a second electrical path between the ground of the electronic device 101 and the remaining terminals (e.g., the third terminal 1103, the fourth terminal 1104, and the fifth terminal 1105), excluding the terminals (e.g., the first terminal 1101 and the second terminal 1102) with which the first RF path is formed. For example, the formed second electrical path may be a DC current path. The switching element 1100-1 may discharge the DC current to the ground through the second inductor 1220 on the DC current path.

As an example, the switching element 1100 may include a substrate, a first conductive pad disposed in a first region of the substrate and configured to be electrically connected to a first signal line disposed outside the switching element 1100, and a second conductive pad disposed in a second region of the substrate. The second conductive pad may be configured to be connected to a second signal line disposed outside, which is electrically connected to an external ground. The switching element 1100 may include a third conductive pad disposed in a third region of the substrate. The third conductive pad may be configured to be connected to a third signal line disposed outside, which is electrically connected to the external ground. The first conductive pad may be electrically connected to one of the second conductive pad and the third conductive pad and may not be connected to the other pad, so as to be configured to define an RF path between the first conductive pad and the one electrically connected pad. The substrate may have no ground pad that is electrically connected to the external ground, other than the first conductive pad, the second conductive pad, and the third conductive pad.

For example, while the second conductive pad is electrically connected to the first conductive pad to form a first RF path, the third conductive pad may be configured not to be connected to the first conductive pad and connected to the external ground through the second inductor connected to the third signal line. While the third conductive pad is electrically connected to the first conductive pad to form a second RF path, the second conductive pad may be configured not to be connected to the first conductive pad and connected to the external ground through the first inductor connected to the second signal line.

For example, the second conductive pad may be configured to be electrically connected to one end of the first inductor 1210. The third conductive pad may be configured to be electrically connected to one end of the second inductor 1220.

As an example, the switching element 1100 may further include multiple terminals 1101, 1102, and 1103 disposed on the substrate and multiple switches 1110, 1120, 1130, and 1140 disposed on the substrate. The multiple terminals 1101, 1102, and 1103 disposed on the substrate may include a first terminal 1101 connected to the first conductive pad, a second terminal 1102 connected to the second conductive pad, and a third terminal 1103 connected to the third conductive pad. The multiple switches 1110, 1120, 1130, and 1140 disposed on the substrate may include a first switch 1110 for connecting the second terminal 1102 to the first terminal 1101 and a second switch 1120 for connecting the third terminal 1103 to the first terminal 1101.

For example, there may be no pad other than the second conductive pad for electrically connecting the second terminal 1102 of the switching element 1100 to the external ground, and there may be no pad other than the third conductive pad for connecting the third terminal 1103 to the external ground.

As an example, the switching element 1100 may further include an internal ground disposed on the substrate. Multiple switches 1110, 1120, 1130, and 1140 disposed on the substrate may include a third switch 1130 for connecting the second terminal 1102 to the internal ground, and a fourth switch 1140 for connecting the third terminal 1103 to the internal ground.

As an example, one end of the third switch 1130 may be connected to the second terminal 1102 and the first switch 1110, and the other end may be connected to the internal ground. One end of the fourth switch 1140 may be connected to the third terminal 1103 and the second switch 1120, and the other end may be connected to the internal ground.

As an example, one end of the first switch 1110 may be connected to one end of the second terminal 1102 and one end of the third switch 1130, and the other end may be connected to one end of the first terminal 1101 and one end of the second switch 1120. One end of the second switch 1120 may be connected to one end of the third terminal 1103 and one end of the fourth switch 1140, and the other end may be connected to one end of the first terminal 1101 and one end of the first switch 1110.

For example, the switching element 1100 may further include a controller 1190. The controller 1190 may be configured to turn on the first switch 1110 and the fourth switch 1140 and to turn off the second switch 1120 and the third switch 1130 so that an RF signal is transmitted between the first terminal 1101 and the second terminal 1102. The controller 1190 may be configured to turn on the second switch 1120 and the third switch 1130 and to turn off the first switch 1110 and the fourth switch 1140 so that an RF signal is transmitted between the first terminal 1101 and the third terminal 1103.

As an example, when the third switch 1130 is turned on, the switching element 1100 may configure a discharge path for discharging a DC current to the external ground through the second terminal 1102, the second conductive pad, and the first inductor 1210. The switching element 1100 may, when the fourth switch 1140 is turned on, configure a discharge path to discharge a DC current to the external ground through the third terminal 1103, the third conductive pad, and the second inductor 1220.

For example, the first conductive pad may be electrically connected to the first element. The second conductive pad and the third conductive pad may be electrically connected to the second element.

For example, the electronic device 101 may include a first element, a second element, a first inductor 1210, a second inductor 1220, a switching element 1100, and a printed circuit board (PCB) on which the first element, the second element, the first inductor 1210, the second inductor 1220, and the switching element 1100 are disposed. The printed circuit board may include a ground, a first signal line electrically connected to the first element, a second signal line electrically connected to a first terminal of the second element and connected to the ground through the first inductor 1210, and a third signal line electrically connected to the second terminal of the second element and connected to the ground through the second inductor 1220.

The switching element may include a substrate, a first conductive pad disposed in a first region of the substrate and electrically connected to the first signal line, a second conductive pad disposed in a second region of the substrate and connected to the second signal line, and a third conductive pad disposed in a third region of the substrate and connected to the third signal line. The first conductive pad may be electrically connected to one of the second conductive pad and the third conductive pad and may not be connected to the other pad, so as to be configured to define an RF path between the first conductive pad and the one electrically connected pad. The substrate may have no ground pad that is electrically connected to external ground, other than the first conductive pad, the second conductive pad, and the third conductive pad.

For example, when the second conductive pad is electrically connected to the first conductive pad to form a first RF path, the third conductive pad may be configured not to be connected to the first conductive pad and connected to the ground through the second inductor 1220 connected to the third signal line. When the third conductive pad is electrically connected to the first conductive pad to form a second RF path, the second conductive pad may be configured not to be connected to the first conductive pad and connected to the ground through the first inductor 1210 connected to the second signal line.

For example, the second conductive pad may be configured to be electrically connected to one end of the first inductor 1210. The third conductive pad may be configured to be electrically connected to one end of the second inductor 1220.

As an example, the switching element 1100 may further include multiple terminals 1101, 1102, and 11030 disposed on the substrate and multiple switches 1110, 1120, 1130, and 1140 disposed on the substrate. The multiple terminals 1101, 1102, and 11030 disposed on the substrate may include a first terminal 1101 connected to the first conductive pad, a second terminal 1102 connected to the second conductive pad, and a third terminal 1103 connected to the third conductive pad. The multiple switches 1110, 1120, 1130, and 1140 disposed on the substrate may include a first switch 1110 for connecting the second terminal 1102 to the first terminal 1101 and a second switch 1120 for connecting the third terminal 1103 to the first terminal 1101.

For example, there may be no pad other than the second conductive pad for electrically connecting the second terminal 1102 of the switching element 1100 to the external ground, and there may be no pad other than the third conductive pad for connecting the third terminal 1103 to the external ground.

As an example, the switching element 1100 may further include an internal ground disposed on the substrate. Multiple switches 1110, 1120, 1130, and 1140 disposed on the substrate may include a third switch 1130 for connecting the second terminal 1102 to the internal ground, and a fourth switch 1140 for connecting the third terminal 1103 to the internal ground.

As an example, one end of the third switch 1130 may be connected to the second terminal 1102 and the first switch 1110, and the other end may be connected to the internal ground. One end of the fourth switch 1140 may be connected to the third terminal 1103 and the second switch 1120, and the other end may be connected to the internal ground.

As an example, one end of the first switch 1110 may be connected to one end of the second terminal 1102 and one end of the third switch 1130, and the other end may be connected to one end of the first terminal 1101 and one end of the second switch 1120. One end of the second switch 1120 may be connected to one end of the third terminal 1103 and one end of the fourth switch 1140, and the other end may be connected to one end of the first terminal 1101 and one end of the first switch 1110.

For example, the switching element 1100 may further include a controller 1190. The controller 1190 may be configured to turn on the first switch 1110 and the fourth switch 1140 and to turn off the second switch 1120 and the third switch 1130 so that an RF signal is transmitted between the first terminal 1101 and the second terminal 1102. The controller may be configured to turn on the second switch 1120 and the third switch 1130 and to turn off the first switch 1110 and the fourth switch 1140 so that an RF signal is transmitted between the first terminal 1101 and the third terminal 1103.

It should be appreciated that various examples of the disclosure and the terms used therein are not intended to limit the technological features set forth herein to particular examples and include various changes, equivalents, or replacements for a corresponding example. With regard to the description of the drawings, similar reference numerals may be used to refer to similar or related elements. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it denotes that the element may be coupled with the other element directly (e.g., wiredly), wirelessly, or via a third element.

As used in connection with various examples of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an example, the module may be implemented in a form of an application-specific integrated circuit (ASIC).

Various examples as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an example, a method according to various examples of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various examples, each component (e.g., a module or a program) of the above-described components may include a single entity or multiple entities, and some of the multiple entities may be separately disposed in different components. According to various examples, one or more of the above-described components may be omitted, or one or more other components may be added. Alternatively or additionally, a plurality of components (e.g., modules or programs) may be integrated into a single component. In such a case, according to various examples, the integrated component may still perform one or more functions of each of the plurality of components in the same or similar manner as they are performed by a corresponding one of the plurality of components before the integration. According to various examples, operations performed by the module, the program, or another component may be carried out sequentially, in parallel, repeatedly, or heuristically, or one or more of the operations may be executed in a different order or omitted, or one or more other operations may be added.

It will be appreciated that various embodiments of the disclosure according to the claims and description in the specification can be realized in the form of hardware, software or a combination of hardware and software.

Any such software may be stored in non-transitory computer readable storage media. The non-transitory computer readable storage media store one or more computer programs (software modules), the one or more computer programs include computer-executable instructions that, when executed by one or more processors of an electronic device, cause the electronic device to perform a method of the disclosure.

Any such software may be stored in the form of volatile or non-volatile storage, such as, for example, a storage device like read only memory (ROM), whether erasable or rewritable or not, or in the form of memory, such as, for example, random access memory (RAM), memory chips, device or integrated circuits or on an optically or magnetically readable medium, such as, for example, a compact disk (CD), digital versatile disc (DVD), magnetic disk or magnetic tape or the like. It will be appreciated that the storage devices and storage media are various embodiments of non-transitory machine-readable storage that are suitable for storing a computer program or computer programs comprising instructions that, when executed, implement various embodiments of the disclosure. Accordingly, various embodiments provide a program comprising code for implementing apparatus or a method of any one of the claims of this specification and a non-transitory machine-readable storage storing such a program.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A switching element comprising:
a substrate;
a first conductive pad disposed in a first region of the substrate and configured to be electrically connected to a first signal line outside the switching element;
a second conductive pad disposed in a second region of the substrate, the second conductive pad being configured to be electrically connected to a second signal line disposed outside and electrically connected to an external ground; and
a third conductive pad disposed in a third region of the substrate, the third conductive pad being configured to be electrically connected to a third signal line disposed outside and electrically connected to the external ground,
wherein the first conductive pad is configured to be electrically connected to one of the second conductive pad or the third conductive pad selectively and unconnected to the other pad so as to form a radio frequency (RF) path between the first conductive pad and the one pad electrically connected thereto, and
wherein the substrate has no ground pad electrically connected to the external ground, except for the first conductive pad, the second conductive pad, and the third conductive pad.

2. The switching element of claim 1,
wherein, while the second conductive pad is electrically connected to the first conductive pad to form a first RF path, the third conductive pad is configured to be unconnected to the first conductive pad and connected to the external ground through a second inductor connected to the third signal line, and
wherein, while the third conductive pad is electrically connected to the first conductive pad to form a second RF path, the second conductive pad is configured to be unconnected to the first conductive pad and connected to the external ground through a first inductor connected to the second signal line.

3. The switching element of claim 2,
wherein the second conductive pad is configured to be electrically connected adjacent to one end of the first inductor, and
wherein the third conductive pad is configured to be electrically connected adjacent to one end of the second inductor.

4. The switching element of claim 3, further comprising:
multiple terminals disposed on the substrate; and
multiple switches disposed on the substrate,
wherein the multiple terminals disposed on the substrate comprise a first terminal connected to the first conductive pad, a second terminal connected to the second conductive pad, and a third terminal connected to the third conductive pad, and
wherein the multiple switches disposed on the substrate comprise a first switch configured to connect the second terminal and the first terminal, and a second switch configured to connect the third terminal and the first terminal.

5. The switching element of claim 4, wherein no conductive pad other than the second conductive pad is provided to electrically connect the second terminal and the external ground, and no conductive pad other than the third conductive pad is provided to connect the third terminal and the external ground.

6. The switching element of claim 4, further comprising:
an internal ground disposed on the substrate,
wherein the multiple switches disposed on the substrate comprise a third switch configured to connect the second terminal and the internal ground, and a fourth switch configured to connect the third terminal and the internal ground.

7. The switching element of claim 6,
wherein one end of the third switch is connected to the second terminal and the first switch, and the other end thereof is connected to the internal ground, and
wherein one end of the fourth switch is connected to the third terminal and the second switch, and the other end thereof is connected to the internal ground.

8. The switching element of claim 6,
wherein one end of the first switch is connected to the second terminal and one end of the third switch, and the other end thereof is connected to the first terminal and one end of the second switch, and
wherein one end of the second switch is connected to the third terminal and one end of the fourth switch, and the other end thereof is connected to the first terminal and one end of the first switch.

9. The switching element of claim 6, further comprising:
at least one processor,
wherein the at least one processor is configured to:
turn on the first switch and the fourth switch and turn off the second switch and the third switch so as to transfer an RF signal between the first terminal and the second terminal, or
turn on the second switch and the third switch and turn off the first switch and the fourth switch so as to transfer an RF signal between the first terminal and the third terminal.

10. The switching element of claim 9, wherein the switching element is configured to:
when the third switch is turned on, form a discharge path to discharge a DC current to the external ground through the second terminal, the second conductive pad, and the first inductor; and
when the fourth switch is turned on, form a discharge path to discharge a DC current to the external ground through the third terminal, the third conductive pad, and the second inductor.

11. The switching element of claim 1,
wherein the first conductive pad is electrically connected to a first element, and
wherein the second conductive pad and the third conductive pad are electrically connected to a second element.

12. An electronic device comprising:
a first element;
a second element;
a first inductor;
a second inductor;
a switching element; and
a printed circuit board (PCB) on which the first element, the second element, the first inductor, the second inductor, and the switching element are disposed,
wherein the PCB comprises:
a ground,
a first signal line electrically connected to the first element,
a second signal line electrically connected to a first terminal of the second element and connected to the ground through the first inductor, and
a third signal line electrically connected to a second terminal of the second element and connected to the ground through the second inductor,
wherein the switching element comprises:
a substrate,
a first conductive pad disposed in a first region of the substrate and electrically connected to the first signal line,
a second conductive pad disposed in a second region of the substrate and connected to the second signal line, and
a third conductive pad disposed in a third region of the substrate and connected to the third signal line,
wherein the first conductive pad is configured to be electrically connected to one of the second conductive pad or the third conductive pad and unconnected to the other pad so as to form a radio frequency (RF) path between the first conductive pad and the one pad electrically connected thereto, and
wherein the substrate has no ground pad electrically connected to the ground, except for the first conductive pad, the second conductive pad, and the third conductive pad.

13. The electronic device of claim 12,
wherein, when the second conductive pad is electrically connected to the first conductive pad to form a first RF path, the third conductive pad is configured to be unconnected to the first conductive pad and connected to the ground through the second inductor connected to the third signal line, and
wherein, when the third conductive pad is electrically connected to the first conductive pad to form a second RF path, the second conductive pad is configured to be unconnected to the first conductive pad and connected to the ground through the first inductor connected to the second signal line.

14. The electronic device of claim 13,
wherein the second conductive pad is configured to be electrically connected to one end of the first inductor, and
wherein the third conductive pad is configured to be electrically connected to one end of the second inductor.

15. The electronic device of claim 12,
wherein the switching element further comprises:
multiple terminals disposed on the substrate, and
multiple switches disposed on the substrate,
wherein the multiple terminals disposed on the substrate comprise a first terminal connected to the first conductive pad, a second terminal connected to the second conductive pad, and a third terminal connected to the third conductive pad, and
wherein the multiple switches disposed on the substrate comprise a first switch configured to connect the second terminal and the first terminal, and a second switch configured to connect the third terminal and the first terminal.
